(19) United States
(12) Patent Application Publication
(10) Pub. No.: US 2017/0331232 A1
(43) Pub. Date: Nov. 16, 2017

(54) RESIDUAL CURRENT MONITOR

(71) Applicant: Bentek Corporation, San Jose, CA (US)

(72) Inventor: David WHITE, Denver, CO (US)

(21) Appl. No.: 15/491,423

(22) Filed: Apr. 19, 2017

Related U.S. Application Data
(60) Provisional application No. 62/336,481, filed on May 13, 2016.
(60) Provisional application No. 62/336,495, filed on May 13, 2016.

(51) Int. Cl. H01R 13/66; H01R 13/713; G01R 15/20; G01R 19/165; H02H 1/00; H01R 25/16

(52) U.S. Cl. CPC H01R 13/6683; H02H 1/0007; H01R 25/162; G01R 15/202; G01R 19/16571; H01R 13/713

(57) ABSTRACT

A residual current monitor measures current using a differential pair of sensors and a device that may cancel common-mode signals and amplify the difference between the two sensor outputs. The sensor output may be zeroed at full-scale output current.

### CROSS REFERENCE TO RELATED APPLICATIONS

This application claims the benefit of U.S. Provisional Application No. 62/336,481, filed on May 13, 2016, and U.S. Provisional Application No. 62/336,495, filed on May 13, 2016, the entire contents of both being incorporated herein by reference.

### BACKGROUND

Electrical power may be generated and distributed in the form of electricity from one or more power sources to end users, sometimes via a power distribution grid. For example, fossil fuel, nuclear, wind, or water power sources may be used to generate and deliver electrical power to one or more end users directly or via a distribution system, which may distribute electricity via power lines constituting a grid to, e.g., residential or commercial end users. Solar or photovoltaic (PV) power may be used similarly to generate and distribute electricity. Solar-sourced electrical power commonly supplements power provided by other sources, although in some applications solar power is the sole source of electricity at the end use.

In a power system, the “balance of systems” (BOS) may comprise components used to modify, distribute, and ultimately deliver electricity generated from the energy source to the end user. For example, in a solar power system, the BOS may include such components as cabling, switches, enclosures, inverters, etc.

All electrical power systems are subject to electrical faults, both environmental (e.g., deteriorated insulation, animal intrusion) and human (e.g., mishandling of tools or protocol failures in installation or maintenance) in origin. Frequently, faults of this type are short circuits between positive and neutral conductors (“line-line” faults) or between positive and grounded conductors (“line-ground” or “ground” faults). Line-ground faults are known to present a risk of fire and damage to property in most types of electrical power systems.

Electrical faults may be divided into bolted faults and arc faults. A bolted fault may be a solid electrical fault path, an example of which is the tool that causes a short circuit. An arc fault may be an energy path between electrical conductors through air without a physical connection between them.

Ground faults may result in a residual current that is detectable as a difference in current between, e.g., positive and neutral (“return”) or positive and ground conductors. Residual currents may result from a variety of faults, including short circuits from environmental causes such as a rodent chewing through the insulation of adjacent wires or contact of a positive conductor with an ungrounded appliance frame. Upon detection, the circuit having the fault can be interrupted substantially instantaneously by triggering a circuit breaker, for example.

Devices exist that perform both the residual current detection and circuit interruption. Such devices are typically hard-wired to the conductors being monitored and may be sensitive to noise and changes in power supply voltage.

### SUMMARY

In a first aspect, a residual current monitor comprises a differential pair of first and second sensors configured to be operably coupled to first and second electrical conductors, respectively; and a device operably coupled to the first and second sensors, to determine and indicate a voltage difference between respective outputs of the first and second sensors; wherein the device includes a threshold detector configured to input an indication of the voltage difference determined by the device and to output a tripping signal in accordance with the voltage difference exceeding a predetermined threshold.

In a second aspect, an electrical junction assembly comprises first electrical circuitry configured to receive two or more direct current inputs via corresponding electrically parallel input conductors and to combine the two or more direct current inputs into one or more direct current outputs on corresponding output conductors, wherein the one or more direct current outputs are fewer in number than the two or more direct current inputs; and a residual current monitor comprising a differential pair of first and second sensors configured to be operably coupled to first and second electrical conductors, respectively, in the first electrical circuitry; and a device operably coupled to the first and second sensors, including second electrical circuitry to indicate a difference in voltage between respective outputs of the first and second sensors; wherein the first electrical circuitry includes an interrupting device to open a circuit in accordance with the indicated difference.

In a third aspect, a method of enhancing safety in an electrical power system having a source of electrical power; a first system including cabling for transmitting electricity from the source to an electrical junction assembly configured with first electrical circuitry to receive two or more direct current inputs via corresponding electrically parallel input conductors for combining into one or more direct current outputs on corresponding output conductors, wherein the one or more direct current outputs are fewer in number than the two or more direct current inputs; and a second system for outputting electricity from the electrical junction assembly for downstream use; comprises installing a residual current monitor in the first electrical circuitry in the electrical junction assembly, the residual current monitor having a differential pair of first and second sensors and a device operably coupled to the first and second sensors; wherein installing the residual current monitor includes operably coupling the differential pair of first and second sensors to first and second electrical conductors, respectively, in the first electrical circuitry, in a manner that enables each of the first and second sensors to output a voltage induced by a current flowing in the first and second electrical conductors, respectively, and in a manner that enables the device to determine and indicate a difference in voltage between the outputs of the first and second sensors; wherein the installing of the residual current monitor in the electrical junction assembly is performed at a location at which the electrical junction assembly is deployed in the electrical power system.

### BRIEF DESCRIPTION OF THE DRAWINGS

The accompanying drawings are considered illustrative of inventive concepts described throughout the disclosure. To the extent that the drawings show inventive concepts, possibly including analysis that is properly considered to be inventive activity, the drawings nevertheless are illustrative in nature and should not be considered unduly limitative in any way.

FIG. 1 illustrates an example of a solar power system.

FIG. 2 illustrates an example of a combiner 30 in which a residual current monitor may be located.

### DETAILED DESCRIPTION

Embodiments are described herein that, for example, provide enhanced protection against electrical faults, and have notable applicability in power distribution systems of which solar power systems are an example. Improvements in safety, both for equipment and personnel, flow from the various embodiments. Other improvements and advantages also flow from the various embodiments, whether or not specifically disclosed. All such improvements and advantages are proper considered within the spirit and scope of the disclosed embodiments, without limitation.

Throughout the description, reference may be made to “electricity”, “current”, “electrical current”, “power”, “electrical power”, or the like. Although these terms may be differentiable by a person of ordinary skill in the art, for convenience, the terms may be used substantially interchangeably in many contexts as is understood by such a person.

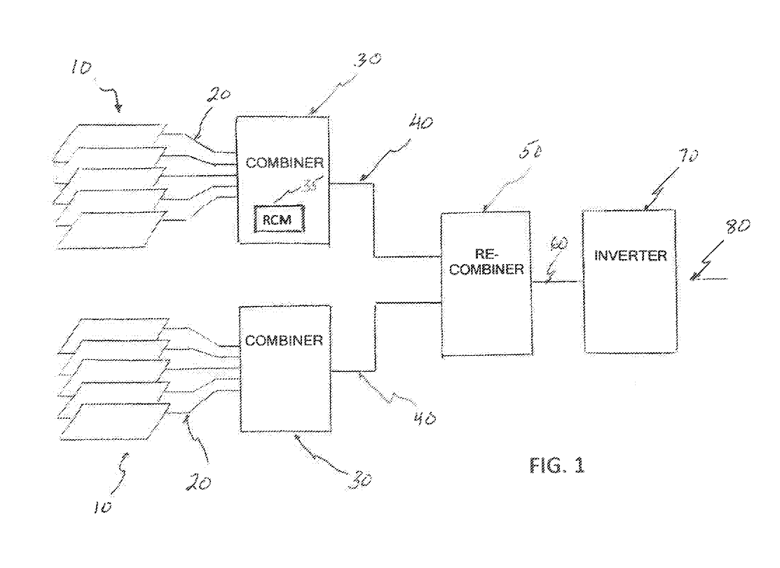

FIG. 1 illustrates an example of an electrical power system. In particular, a solar power system is shown as representative. Although a solar power system is illustrated, one of ordinary skill in the art will readily understand that other power systems utilizing similar components may have similar issues that may be addressed by the presently disclosed embodiments. For example, electrical power generated from fossil fuel or other energy sources, DC battery systems in off-grid solar applications or other energy storage systems of various scales, electric vehicles and their charging stations, and the like may be distributed using similar components or concepts.

The solar power system represented by FIG. 1 may include, for example, a plurality of strings 10 each comprising one or more solar or photovoltaic (PV) panels (modules) in series. At least some of strings 10 may be arranged in electrical parallel. Each string 10 may output direct current power from the last module in the series via one or more conductors 20, which provide the direct current as an input to a combiner 30. In accordance with the parallel nature of strings 10, the direct current inputs to combiner 30 may be parallel inputs. In combiner 30, the direct current inputs are combined into one output via a conductor 40.

In some embodiments, the inputs to combiner 30 may be direct current (DC), single-phase alternating current (AC), or three-phase AC (summed, with optional neutral) inputs via corresponding conductors, and combined into one or more direct current outputs.

In some embodiments, one or more combiners 30 each may combine the direct current inputs into a plurality of outputs, the number of which is fewer than the number of inputs. The plurality of outputs in such embodiments may then be provided via conductors 40 as inputs to a recombiner 50, which may combine the inputs into one output provided via a conductor 60 as an input to an inverter 70. Inverter 70 may convert the DC input to alternating current (AC) for output via one or more conductors 80, e.g., to a residential user or to a power grid for further distribution.

In some embodiments, multiple combiners and recombiners may be arranged in a similar fashion as desired, for example depending on the scale of the power system. In such embodiments, the multiple combiners and recombiners may be stacked, with one or more inputs combined and recombined, respectively, as needed, ultimately providing the output as an input to inverter 70.

In some embodiments, a residual current monitor (RCM) 35 may be provided in combiner 30. RCM 35 may provide circuit protection (and corresponding system and personal safety) in the form of a substantially instantaneous interruption in the case of detecting a residual current as discussed below.

In some embodiments, combiner 30 and/or recombiner 50 may be located inside an enclosure configured to be opened and closed. In such embodiments, combiner 30 may be termed a “combiner box” and recombiner 50 may be termed a “recombiner box”. In this description, “combiner” and “combiner box” (and “recombiner” and “recombiner box”) may be interchangeable as regards features of the disclosed embodiments. In a combiner box, at least the combiner circuitry, including the RCM, may be housed in both of the opened and closed configurations, and likewise for a recombiner box.

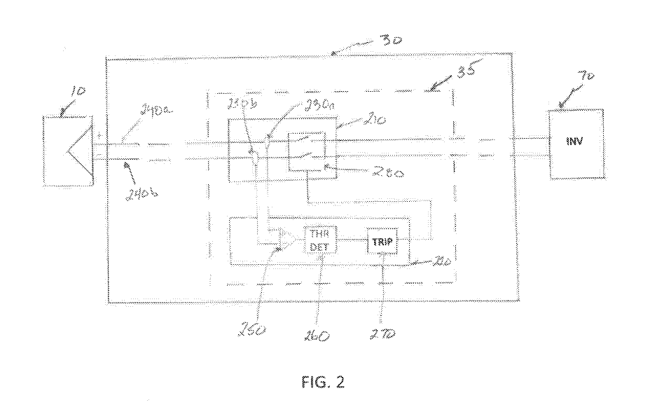

FIG. 2 illustrates an example of combiner 30 in which an RCM 35 may be located. As shown, combiner 30 receives power from one or more PV panels 10 and delivers power to inverter 70. For clarity, no recombiner is illustrated and only one PV panel 10 is shown. FIG. 2 does not illustrate all components of combiner 30 so as to highlight RCM 35.

In the example shown, RCM 35 may comprise a residual current detector 210 and a trip actuator 220. RCM 35 may employ a pair of DC current sensors 230a, 230b operatively coupled to first and second conductors 240a, 240b, respectively. Sensors 230a, 230b may be DC current transducers or Hall-effect sensors and may be matched, for example. In some embodiments, RCM 35 may be a bi-directional, DC monitor that trips on positive and negative currents.

As shown, first and second conductors 240a, 240b may carry current within combiner 30. First and second conductors 240a, 240b may be positive and neutral conductors or positive and grounded conductors, respectively. For example, first conductor 240a may be a positive conductor and second conductor 240b may be either a neutral conductor or a grounded conductor. Conversely, second conductor 240b may be a positive conductor and first conductor 240a may be either a neutral conductor or a grounded conductor.

In an embodiment in which first conductor 240a is a positive conductor and second conductor 240b is a neutral conductor, currents flowing in first and second conductors 240a, 240b may be equal in value and opposite in direction in ordinary operation. Sensors 230a, 230b may sense the currents flowing in first and second conductors 240a, 240b, respectively and output voltage signals induced by and indicative of the respectively-sensed currents.

In some embodiments, trip actuator 220 may include a device 250 operably connected to the outputs of sensors 230a, 230b at respective inputs thereof. Device 250 may be configured to include circuitry to input the outputs of sensors 230a, 230b and output a signal or other indication representing the difference in voltage between the two inputs. Nonlimiting examples of device 250 may be a differential amplifier, an instrumentation amplifier, or software coupled with appropriate hardware to effect the difference signal or other indication. Other suitable components to determine the voltage difference, such as analog-to-digital converters provided independently or functionally incorporated with, e.g., a digital signal processor (DSP) or microcontroller, are also contemplated.

An output of device 250 may be input to a threshold detector 260. Threshold detector 260 may comprise software and/or hardware (such as circuitry) to detect whether the voltage difference exceeds a predetermined threshold. The voltage difference may be detected directly or indirectly, such as by an operation that represents the voltage difference in a different form. Threshold detector 260 provides an output at least in response to detecting that the voltage difference exceeds the predetermined threshold. In such a case, the signal may be output to a tripping device 270 configured to provide a signal to effect opening of an interrupting device 280. Interrupting device may take any form appropriate to the environment and application. In one example, interrupting device 280 may be a circuit breaker opened (“tripped”) by the trip actuator output, thereby preventing the residual current from causing damage.

In some embodiments, signals sensed by sensors 230a, 230b may be modified or processed. In an example employing a differential amplifier in trip actuator 220, the signal output by device 250 may be rectified by device 250 or another device. In some examples, hysteresis may be added to prevent oscillation at the threshold detector 260. Pulse-width modulation may be included for more precise signal measurement. Pulse-width modulation and other signal modification and/or processing may be performed at sensors 230a, 230b, for example by utilizing a Hall-effect or other sensor IC with appropriate on-board processing capabilities. By this or similar solution, effects of environmental noise may be reduced or prevented. Other methods of signal detection and/or modulation will become apparent to one of ordinary skill in the art.

Interrupting device 280 may be integrated or incorporated into residual current detector 210 as shown; integrated or incorporated into RCM 35 separately from residual current detector 210, or provided separately from RCM 35. As one nonlimiting example, a circuit including the conductor on which the residual current was detected may be interrupted. Alternatively or in addition, a different circuit in the combiner may be interrupted, by way of example only, via a remote shunt trip switch exclusive of interrupting device 280.

In conjunction with sensors 230a, 230b, RCM 35 may provide improved safety protection for both equipment and personnel. For example, utilizing “matched” sensors may permit residual current detection in accordance with the difference between the sensor outputs, enabling reduction or cancellation of a variety of disturbances, including common-mode disturbances (e.g., signals, hysteresis, temperature coefficients, systemic drift of components over time, etc.), to at least reduce noise and provide improved accuracy in response. In addition, utilizing Hall-effect sensors permits detection of residual current in the presence of a DC bias current, and using the effective sensor(s) at full-scale input current. Such capability may be useful to additionally divert the output current measurement to an energy monitoring system or a SCADA system.

In one or more embodiments, an AC-based product may form the “current sensor” using a current transformer, while a DC or AC/DC device may use Hall-effect sensors. Suitable Hall-effect sensors may include an integrated circuit or a Hall element and associated electronics with a magnetic concentrator or “core” as an assembly, for example. Other solutions will be apparent to one of ordinary skill in the art.

In the example illustrated in FIG. 2, RCM 35 may comprise residual current detector 210 and trip actuator 220 as separate circuits and/or software. However, residual current detector 210 and trip actuator 220 may be seen as being portions of the same circuit and/or software and constructed accordingly. Furthermore, RCM 35 may comprise residual current detector 210, with trip actuator 220 provided as one or more separate components. Conversely RCM 35 may comprise trip actuator 220 having one or more of the components shown, with residual current detector 210 provided as one or more separate components. Moreover, RCM 35 may be attachable or detachable (installed or uninstalled) off site or on site (for example in the combiner enclosure or “combiner box”).

Although various features, advantages, and improvements have been described in accordance with the embodiments shown, such are to be considered as examples only and not limitative of the features and benefits that flow from the disclosed embodiments. Furthermore, one of ordinary skill in the art will readily recognize variations and modifications to the embodiments as disclosed, which themselves provide the same or additional features, advantages, and improvements. All such variations and modifications that basically rely on the inventive concepts by which the art has been advanced are properly considered within the spirit and scope of the invention.

What is claimed is:

1. A residual current monitor, comprising:
a differential pair of first and second sensors configured to be operably coupled to first and second electrical conductors, respectively; and
a device operably coupled to the first and second sensors, to determine and indicate a voltage difference between respective outputs of the first and second sensors;
wherein the device includes a threshold detector configured to input an indication of the voltage difference determined by the device and to output a tripping signal in accordance with the voltage difference exceeding a predetermined threshold.

2. The residual current monitor of claim 1, wherein the residual current monitor is configured to be attachable and detachable from operable coupling of the first and second sensors to the first and second electrical conductors.

3. The residual current monitor of claim 1, further comprising an interrupting device to open a circuit in accordance with the indicated difference.

4. The residual current monitor of claim 3,
wherein the interrupting device is located in series with at least one of the input conductors.

5. The residual current monitor of claim 4, further comprising a tripping device;
wherein the interrupting device is a remotely controlled switch configured to be tripped by a signal from the tripping device.

6. The residual current monitor of claim 1, wherein the device includes a differential amplifier.

7. The residual current monitor of claim 1, wherein the first and second sensors include Hall-effect sensors.

8. The residual current monitor of claim 1, further comprising an interrupting device located in series with at least one of the input conductors.
wherein the device includes a tripping switch configured to receive the tripping signal output by the threshold detector; and
wherein the interrupting device is a remotely controlled switch configured to be tripped by a signal from the tripping device.

9. An electrical junction assembly, comprising:
first electrical circuitry configured to receive two or more direct current inputs via corresponding electrically parallel input conductors and to combine the two or more direct current inputs into one or more direct current outputs on corresponding output conductors, wherein the one or more direct current outputs are fewer in number than the two or more direct current inputs; and
a residual current monitor comprising:
a differential pair of first and second sensors configured to be operably coupled to first and second electrical conductors, respectively, in the first electrical circuitry; and
a device operably coupled to the first and second sensors, including second electrical circuitry to indicate a difference in voltage between respective outputs of the first and second sensors;
wherein the first electrical circuitry includes an interrupting device to open a circuit in accordance with the indicated difference.

10. The electrical junction assembly of claim 9, further comprising:
an electrical junction assembly enclosure configured to be opened and closed, in which the first electrical circuitry and residual current monitor are housed in both of the opened and closed configurations.

11. The electrical junction assembly of claim 10, wherein the residual current detector is configured to be attachable and detachable from operable coupling of the first and second sensors to the first and second electrical conductors within the electrical junction assembly enclosure.

12. The electrical junction assembly of claim 9, wherein first and second sensors include Hall-effect sensors.

13. The electrical junction assembly of claim 9,
wherein the interrupting device is located in series with at least one of the input conductors.

14. The electrical junction assembly of claim 13, further comprising a tripping device;
wherein the interrupting device is a remotely controlled switch configured to be tripped by a signal from the tripping device.

15. The electrical junction assembly of claim 9, wherein the residual current monitor includes a circuit protector.

16. The electrical junction assembly of claim 9, wherein the device includes a differential amplifier.

17. A method of enhancing safety in an electrical power system having a source of electrical power; a first system including cabling for transmitting electricity from the source to an electrical junction assembly configured with first electrical circuitry to receive two or more direct current inputs via corresponding electrically parallel input conductors for combining into one or more direct current outputs on corresponding output conductors, wherein the one or more direct current outputs are fewer in number than the two or more direct current inputs; and a second system for outputting electricity from the electrical junction assembly for downstream use; the method comprising:
installing a residual current monitor in the first electrical circuitry in the electrical junction assembly, the residual current monitor having a differential pair of first and second sensors and a device operably coupled to the first and second sensors;
wherein installing the residual current monitor includes operably coupling the differential pair of first and second sensors to first and second electrical conductors, respectively, in the first electrical circuitry, in a manner that enables each of the first and second sensors to output a voltage induced by a current flowing in the first and second electrical conductors, respectively, and in a manner that enables the device to determine and indicate a difference in voltage between the outputs of the first and second sensors;
wherein the installing of the residual current monitor in the electrical junction assembly is performed at a location at which the electrical junction assembly is deployed in the electrical power system.

18. The method of claim 17, wherein the differential pair of first and second sensors include Hall-effect sensors.

19. The method of claim 17, further comprising accessing the electrical junction assembly in an electrical junction assembly enclosure that houses at least electrical connection points of the input conductors and output conductors and the residual current monitor within the electrical junction assembly enclosure at the location of deployment in the electrical power system.

20. The method of claim 17, wherein the installing of the residual current detector is performed so as to permit the residual current monitor to be uninstalled within the electrical junction assembly enclosure.
